(19) United States
(12) Patent Application Publication
(10) Pub. No.: US 2026/0268827 A1
(43) Pub. Date: Sep. 10, 2026

(54) SHIFT REGISTER UNIT, DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN); Beijing BOE Technology Development Co., Ltd., Beijing (CN)

(72) Inventors: Yao HUANG, Beijing (CN); Mengmeng DU, Beijing (CN); Ansu LEE, Beijing (CN); Xiangdan DONG, Beijing (CN); Ming HU, Beijing (CN); Haijun QIU, Beijing (CN)

(21) Appl. No.: 19/160,568

(22) PCT Filed: Aug. 16, 2024
(86) PCT No.: PCT/CN2024/112607

§ 371 Date: Aug. 28, 2025

(30) Foreign Application Priority Data
Nov. 30, 2023 (CN) 202311621298.3

(51) Int. Cl. G09G 3/20; G11C 19/28

(52) U.S. Cl. CPC G09G 3/2092; G09G 2310/0286; G09G 2310/08; G09G 2320/043; G11C 19/287

(57) ABSTRACT

A shift register unit includes a first output transistor, a gate driving signal output end, a first output control node, a control signal input end and a first signal input end. The first output transistor includes a dual-gate structure, a first gate electrode of the first output transistor is coupled to the first output control node, a second gate electrode of the first output transistor is coupled to the control signal input end, a first electrode of the first output transistor is coupled to the first signal input end, and a second electrode of the first output transistor is coupled to the gate driving signal output end.

### CROSS-REFERENCE TO RELATED APPLICATION

This application is the U.S. national phase of PCT Application No. PCT/CN2024/112607 filed on Aug. 16, 2024, which claims a priority of the Chinese patent application No. 202311621298.3 filed on Nov. 30, 2023, which is incorporated herein by reference in its entirety.

### TECHNICAL FIELD

The present disclosure relates to the field of display technology, in particular to a shift register unit, a display substrate and a display device.

### BACKGROUND

Along with the continuous development of the display technology, display products are applied more and more widely, and the display quality of the display products is increasingly demanded. In order to further reduce a width of a bezel of a display device and improve driving performance of the display product, usually a Gate On Array (GOA) technique is adopted. In the GOA technique, a gate driving circuit is integrated in a peripheral region of an array substrate in the display product. In this way, on a basis of a fact that merely several control signals are provided by an external circuit, the gate driving circuit is formed through a same process as a thin film transistor, so as to achieve a progressive scanning driving function.

Usually, the gate driving circuit includes a plurality of cascaded shift register units, and the shift register unit includes a plurality of thin film transistors. In the related art, stability of a gate driving signal outputted by the shift register unit is affected to some extent by characteristics of the thin film transistor, and thereby the display quality of the display product is adversely affected.

### SUMMARY

An object of the present disclosure is to provide a shift register unit, a display substrate and a display device.

In order to achieve the above-mentioned object, the present disclosure provides the following technical solutions.

In one aspect, the present disclosure provides in some embodiments a shift register unit, including a first output transistor, a gate driving signal output end, a first output control node, a control signal input end and a first signal input end. The first output transistor includes a dual-gate structure, a first gate electrode of the first output transistor is electrically coupled to the first output control node, a second gate electrode of the first output transistor is coupled to the control signal input end, a first electrode of the first output transistor is coupled to the first signal input end, and a second electrode of the first output transistor is coupled to the gate driving signal output end.

In a possible embodiment of the present disclosure, the shift register unit further includes a second output transistor, a second output control node and a first level signal input end; a gate electrode of the second output transistor is coupled to the second output control node, a first electrode of the second output transistor is coupled to the first level signal input end, and a second electrode of the second output transistor is coupled to the gate driving signal output end; the first signal input end includes a first clock signal input end; the shift register unit further includes a second level signal input end, a third level signal input end and a control signal debugging unit, and the control signal debugging unit includes a first debugging sub-unit and a second debugging sub-unit; the first debugging sub-unit is coupled to the first clock signal input end, the second output control node, the second level signal input end and the control signal input end, and configured to control the second level signal input end to be electrically coupled to or electrically decoupled from the control signal input end under the control of the first clock signal input end and the second output control node; and the second debugging sub-unit is coupled to the first output control node, the third level signal input end and the control signal input end, and configured to control the third level signal input end to be electrically coupled to or electrically decoupled from the control signal input end under the control of the first output control node.

In a possible embodiment of the present disclosure, the first debugging sub-unit includes a first debugging transistor and a second debugging transistor; the second debugging sub-unit includes a third debugging transistor; a gate electrode of the first debugging transistor is coupled to the first clock signal input end, a first electrode of the first debugging transistor is coupled to a second electrode of the second debugging transistor, and a second electrode of the first debugging transistor is coupled to the control signal input end; a gate electrode of the second debugging transistor is coupled to the second output control node, and a first electrode of the second debugging transistor is coupled to the second level signal input end; and a gate electrode of the third debugging transistor is coupled to the first output control node, a first electrode of the third debugging transistor is coupled to the third level signal input end, and a second electrode of the third debugging transistor is coupled to the control signal input end.

In a possible embodiment of the present disclosure, the shift register unit further includes a first node control unit, a second node control unit, a second clock signal input end and a start signal input end; the first node control unit is coupled to the second clock signal input end, the first output control node and the start signal input end, and configured to control the start signal input end to be electrically coupled to or electrically decoupled from the first output control node under the control of the second clock signal input end, wherein the second node control unit is coupled to the first clock signal input end, the second clock signal input end, the first level signal input end, the third level signal input end and the second output control node, and configured to control the first level signal input end to be electrically coupled to or electrically decoupled from the second output control node under the control of the first clock signal input end, and control the third level signal input end to be electrically coupled to or electrically decoupled from the second output control node under the control of the second clock signal input end; or the second node control unit is coupled to the second clock signal input end, the first output control node, the second output control node and the third level signal input end, and configured to control the third level signal input end to be electrically coupled to or electrically decoupled from the second output control node under the control of the second clock signal input end, and control the second clock signal input end to be electrically coupled to or electrically decoupled from the second output control node under the control of the first output control node.

In a possible embodiment of the present disclosure, the first node control unit is further coupled to the first clock signal input end, the second output control node and the first level signal input end, and configured to control the first level signal input end to be electrically coupled to or electrically decoupled from the first output control node under the control of the first clock signal input end and the second output control node.

In a possible embodiment of the present disclosure, the first signal input end includes a first level signal input end, the control signal input end includes a second level signal input end, and the second level signal input end is configured to input a direct-current second level signal; and the shift register unit further includes a second output transistor, a second output control node and a third level signal input end, a gate electrode of the second output transistor is coupled to the second output control node, a first electrode of the second output transistor is coupled to the third level signal input end, and a second electrode of the second output transistor is coupled to the gate driving signal output end.

In a possible embodiment of the present disclosure, the shift register unit further includes a first node control unit, and the first node control unit is coupled to the second output control node, the first level signal input end and the first output control node, and configured to control the first level signal input end to be electrically coupled to or electrically decoupled from the first output control node under the control of the second output control node.

In a possible embodiment of the present disclosure, the first node control unit is further coupled to the second level signal input end, the first node control unit includes a first control transistor, the first control transistor includes a dual-gate structure, a first gate electrode of the first control transistor is coupled to the second output control node, a second gate electrode of the first control transistor is coupled to the second level signal input end, a first electrode of the first control transistor is coupled to the first level signal input end, and a second electrode of the first control transistor is coupled to the first output control node.

In a possible embodiment of the present disclosure, the shift register unit further includes a second node control unit, a third clock signal input end and a start signal input end, and the second node control unit is coupled to the third clock signal input end, the start signal input end and the second output control node, and configured to control the start signal input end to be electrically coupled to or electrically decoupled from the second output control node under the control of the third clock signal input end.

In a possible embodiment of the present disclosure, the second node control unit is further coupled to the third level signal input end; the second node control unit includes a second control transistor, a third control transistor and a fourth control transistor; a gate electrode of the second control transistor is coupled to the third clock signal input end, a first electrode of the second control transistor is coupled to the start signal input end, and a second electrode of the second control transistor is coupled to a first electrode of the third control transistor; a gate electrode of the third control transistor is coupled to the third clock signal input end, and a second electrode of the third control transistor is coupled to the second output control node; and a gate electrode of the fourth control transistor is coupled to the second output control node, a first electrode of the fourth control transistor is coupled to the third level signal input end, and a second electrode of the fourth control transistor is coupled to the first electrode of the third control transistor.

In a possible embodiment of the present disclosure, the first node control unit is further coupled to the first level signal input end, the third level signal input end and the start signal input end, and configured to control the third level signal input end to be electrically coupled to or electrically decoupled from the first output control node under the control of the first level signal input end and the start signal input end.

In another aspect, the present disclosure provides in some embodiments a display substrate including the above-mentioned shift register unit. The display substrate includes a display region and a peripheral region outside the display region, and the shift register unit is arranged in the display region and/or the peripheral region.

In a possible embodiment of the present disclosure, the shift register unit includes a control signal debugging unit, the control signal debugging unit includes a first debugging sub-unit and a second debugging sub-unit, the first debugging sub-unit includes a first debugging transistor and a second debugging transistor, and the second debugging sub-unit includes a third debugging transistor; the shift register unit further includes a first output transistor and a second output transistor; the first output transistor and the second output transistor are arranged in a first direction; at least a portion of the third debugging transistor, the first debugging transistor and the second debugging transistor are arranged in the first direction; and the first output transistor is arranged between the display region and the first debugging transistor.

In a possible embodiment of the present disclosure, the second debugging transistor and the second output transistor both include a dual-gate structure, a first gate electrode of the second debugging transistor and a first gate electrode of the second output transistor form a one-piece structure, and a second gate electrode of the second debugging transistor and a second gate electrode of the second output transistor form a one-piece structure.

In a possible embodiment of the present disclosure, a gate electrode of the third debugging transistor and a first gate electrode of the first output transistor form a one-piece structure.

In a possible embodiment of the present disclosure, the display substrate further includes a second level signal line, And the second level signal line, as a second level signal input end, is coupled to the second debugging transistor; the first debugging transistor includes a first debugging active layer, the second debugging transistor includes a second debugging active layer, and the third debugging transistor includes a third debugging active layer; and an orthogonal projection of the second level signal line onto a base substrate of the display substrate at least partially overlaps with an orthogonal projection of the first debugging active layer onto the base substrate of the display substrate, and/or the orthogonal projection of the second level signal line onto the base substrate of the display substrate at least partially overlaps with an orthogonal projection of the second debugging active layer onto the base substrate of the display substrate, and/or the orthogonal projection of the second level signal line onto the base substrate of the display substrate at least partially overlaps with an orthogonal projection of the third debugging active layer onto the base substrate of the display substrate.

In a possible embodiment of the present disclosure, the display substrate further includes a first level signal line and a third level signal line; the first level signal line, as a first level signal input end, is coupled to the second output transistor, and the third level signal line, as a third level signal input end, is coupled to the third debugging transistor; and in a direction close to the display region, an orthogonal projection of the third level signal line onto the base substrate, an orthogonal projection of the first level signal line onto the base substrate and the orthogonal projection of the second level signal line onto the base substrate are arranged sequentially.

In a possible embodiment of the present disclosure, the display substrate further includes a first clock signal line, a second clock signal line and a start signal line; the first clock signal line, as a first clock signal input end, is coupled to the first debugging transistor; the shift register unit further includes a fifth transistor, a sixth transistor, a seventh transistor and an eighth transistor; a gate electrode of the fifth transistor is coupled to the second clock signal line, a first electrode of the fifth transistor is coupled to the third level signal line, and a second electrode of the fifth transistor is coupled to a gate electrode of the second output transistor; a gate electrode of the sixth transistor is coupled to the first clock signal line, a first electrode of the sixth transistor is coupled to the first level signal line, and a second electrode of the sixth transistor is coupled to the gate electrode of the second output transistor; a gate electrode of the seventh transistor is coupled to the second clock signal line, a first electrode of the seventh transistor is coupled to the start signal line, a second electrode of the seventh transistor is coupled to a first electrode of the eighth transistor, a second electrode of the eighth transistor is coupled to a gate electrode of the first output transistor, and a gate electrode of the eighth transistor is coupled to the third level signal line; the seventh transistor, the eighth transistor, the sixth transistor and the fifth transistor are arranged sequentially in the first direction; and an orthogonal projection of the seventh transistor onto the base substrate, an orthogonal projection of the eighth transistor onto the base substrate, an orthogonal projection of the sixth transistor onto the base substrate and an orthogonal projection of the fifth transistor onto the base substrate are arranged between the orthogonal projection of the third level signal line onto the base substrate and the orthogonal projection of the first level signal line onto the base substrate.

In a possible embodiment of the present disclosure, in the direction close to the display region, the start signal line, the second clock signal line, the first clock signal line and the third level signal line are arranged sequentially.

In yet another aspect, the present disclosure provides in some embodiments a display device including the above-mentioned display substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a circuit diagram of a shift register unit according to an embodiment of the present disclosure;

FIG. 2 is a sequence diagram of the shift register unit in FIG. 1;

FIG. 3 is an oscillogram of a gate driving signal corresponding to different voltage values of a threshold voltage shift for the shift register unit in FIG. 1;

FIG. 4 is a schematic view showing a dual-gate transistor according to an embodiment of the present disclosure;

FIG. 5 is a characteristic curve of different bottom-gate voltages according to an embodiment of the present disclosure;

FIG. 6 is a schematic view showing a dual-gate transistor according to an embodiment of the present disclosure;

FIG. 7 is an oscillogram of signals corresponding to a top gate electrode and a bottom gate electrode according to an embodiment of the present disclosure;

FIG. 8 is a schematic view showing changes in voltages at a control signal input end corresponding to changes in a voltage value of a second level signal according to an embodiment of the present disclosure;

FIG. 9 is a circuit diagram of the shift register unit according to an embodiment of the present disclosure;

FIG. 10 is a sequence diagram of the shift register unit in FIG. 9;

FIG. 11 is an oscillogram of a gate driving signal corresponding to different voltage values of a threshold voltage shift for the shift register unit in FIG. 9;

FIG. 12 is a circuit diagram of the shift register unit according to an embodiment of the present disclosure;

FIG. 13 is a circuit diagram of the shift register unit according to an embodiment of the present disclosure;

FIG. 14 is a circuit diagram of the shift register unit according to an embodiment of the present disclosure;

FIG. 15 is an oscillogram of a gate driving signal corresponding to different voltage values of a threshold voltage shift for the shift register unit in FIG. 14;

FIG. 16 is a circuit diagram of the shift register unit according to an embodiment of the present disclosure;

FIG. 17 is an oscillogram of a gate driving signal corresponding to different voltage values of a threshold voltage shift for the shift register unit in FIG. 16;

FIG. 18 is a schematic view showing the layout of a first gate metal layer of the shift register unit according to one embodiment of the present disclosure;

FIG. 19 is a schematic view showing the layout of the shift register unit in FIG. 18 with a second gate metal layer;

FIG. 20 is a schematic view showing the layout of the shift register unit in FIG. 19 with the second gate metal layer;

FIG. 21 is a schematic view showing the layout of the shift register unit in FIG. 19 with an oxide active layer;

FIG. 22 is a schematic view showing the layout of the shift register unit in FIG. 21 with the oxide active layer;

FIG. 23 is a schematic view showing the layout of the shift register unit in FIG. 21 with a third gate metal layer;

FIG. 24 is a schematic view showing the layout of the shift register unit in FIG. 23 with the third gate metal layer;

FIG. 25 is a schematic view showing the layout of the shift register unit in FIG. 23 with a first source/drain metal layer;

FIG. 26 is a schematic view showing the layout of the shift register unit in FIG. 25 with the first source/drain metal layer; and

FIG. 27 is a schematic view showing the layout of the shift register unit in FIG. 25 with a second source/drain metal layer.

### DETAILED DESCRIPTION

In order to further describe a shift register unit, a display substrate and a display device in the embodiments of the present disclosure, the following detailed description will be given in conjunction with the drawings.

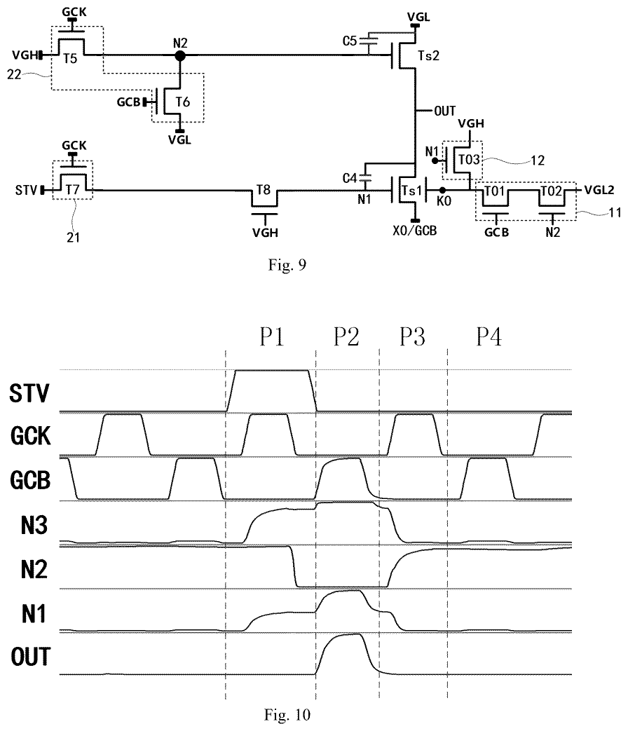

As shown in FIGS. 9 to 14, the present disclosure provides in some embodiments a shift register unit, which includes a first output transistor Ts1, a gate driving signal output end OUT, a first output control node N1, a control signal input end K0 and a first signal input end X0. The first output transistor Ts1 includes a dual-gate structure, a first gate electrode of the first output transistor Ts1 is electrically coupled to the first output control node N1, a second gate electrode of the first output transistor Ts1 is coupled to the control signal input end K0, a first electrode of the first output transistor Ts1 is coupled to the first signal input end X0, and a second electrode of the first output transistor Ts1 is coupled to the gate driving signal output end OUT.

Illustratively, the shift register unit is applied to a gate driving circuit, and the gate driving circuit includes a plurality of the cascaded shift register units. For example, the shift register unit includes, but not limited to, a Gate GOA and a light-emission (EM) GOA.

Illustratively, the display device includes a display region and a peripheral region outside the display region. The display region includes a plurality of subpixels arranged in an array, and a plurality of subpixel driving circuits included in the plurality of subpixels includes a plurality of subpixel driving circuit rows.

Illustratively, the display device further includes a plurality of gate lines, and the gate line is coupled to the subpixel driving circuits in a corresponding row, so as to provide a gate driving signal to the subpixel driving circuit. In a case that the subpixel driving circuit has a 7T1C structure (including 7 transistors and 1 capacitor), a compensation transistor and/or a data write-in transistor of the subpixel driving circuit are coupled to the gate line, but the present disclosure is not limited thereto. For example, in the peripheral region, the gate driving circuit includes a gate-control gate driving circuit, and the gate-control gate driving circuit includes a plurality of cascaded Gate GOA, and the gate driving signal output end OUT of each Gate GOA is coupled to a corresponding gate line.

Illustratively, the display device further includes a plurality of light-emission control signal lines, and the light-emission control signal line is coupled to the subpixel driving circuits in a corresponding row, so as to provide a light-emission control signal to the subpixel driving circuits. In a case that the subpixel driving circuit has a 7T1C structure, a power source control transistor and a light-emission control transistor of the subpixel driving circuit are coupled to the light-emission control signal line, but the present disclosure is not limited thereto. For example, in the peripheral region, the gate driving circuit includes a light-emission control gate driving circuit, and the light-emission control gate driving circuit includes a plurality of cascaded EM GOAs, and the gate driving signal output end OUT of each EM GOA is coupled to a corresponding light-emission control signal line.

Illustratively, the shift register unit includes a plurality of transmissions, and the transistor includes, but not limited to, an oxide transistor.

Illustratively, the first electrode includes a source electrode and the second electrode includes a drain electrode; or the first electrode includes a drain electrode and the second electrode includes a source electrode.

Illustratively, the first gate electrode of the first output transistor Ts1 is coupled to the first output control node N1, the second gate electrode of the first output transistor Ts1 is coupled to the control signal input end K0, and the first output transistor Ts1 is configured to control the first signal input end X0 to be electrically coupled to or electrically decoupled from the gate driving signal output end OUT under the joint control of the first output control node N1 and the control signal input end K0.

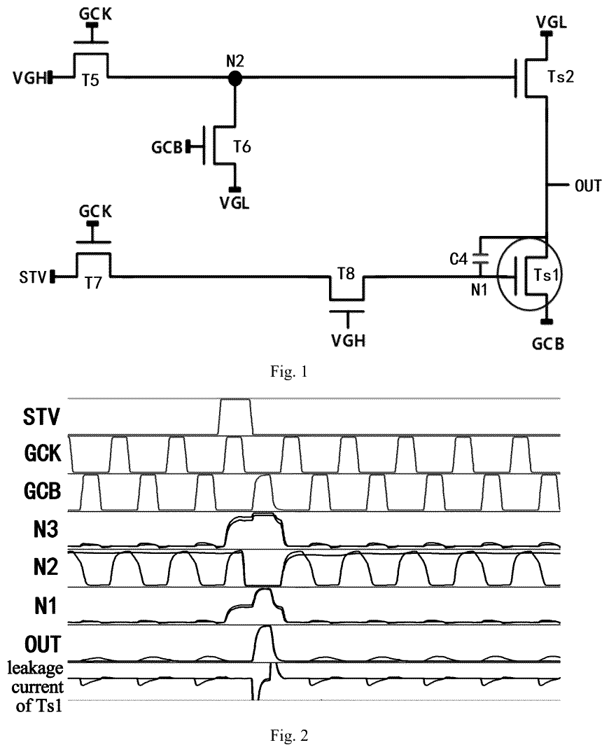

More specifically, as shown in FIGS. 1 and 2, abnormalities occur for output waveforms of the nodes and the gate driving signal output end OUT after a threshold voltage (VTH) shift, e.g., a negative VTH shift, occurs for the first output transistor Ts1 in the shift register unit. A main reason for the abnormalities lies in that, the first output transistor Ts1 is turned on due to a negative-shift current leakage, and a first clock signal input end GCB is coupled to the gate driving signal output end OUT and a leakage current occurs due to an increase in a parasitic capacitance, so burrs occur for a signal waveform, and thereby Mura occurs after the negative VTH shift. Simulation shows that, a main transistor negative-shift point is the first output transistor Ts1, so through improving the structure of the first output transistor Ts1 and the control signal thereof, it is able to improve the negative shift of the first output transistor Ts1, thereby to improve the outputted gate driving signal. It should be appreciated that, in FIG. 2, N3 represents a node between a seventh transistor T7 and an eighth transistor T8 in FIG. 1.

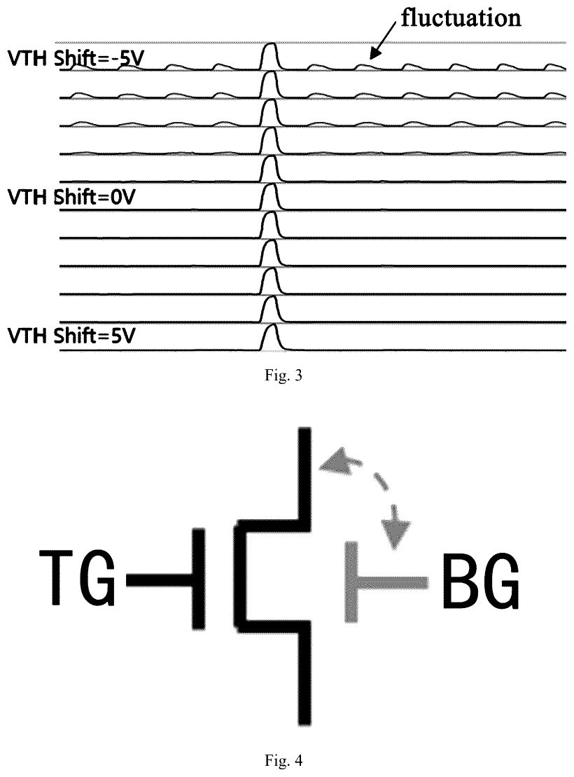

As shown in FIG. 4, in a case that the first output transistor Ts1 has a dual-gate structure, the first gate electrode of the first output transistor Ts1 is defined as a top gate electrode TG, and the second gate electrode of the first output transistor Ts1 is defined as a bottom gate electrode BG. Through adjusting a voltage at the bottom gate electrode BG, it is able to adjust a threshold voltage of the first output transistor Ts1.

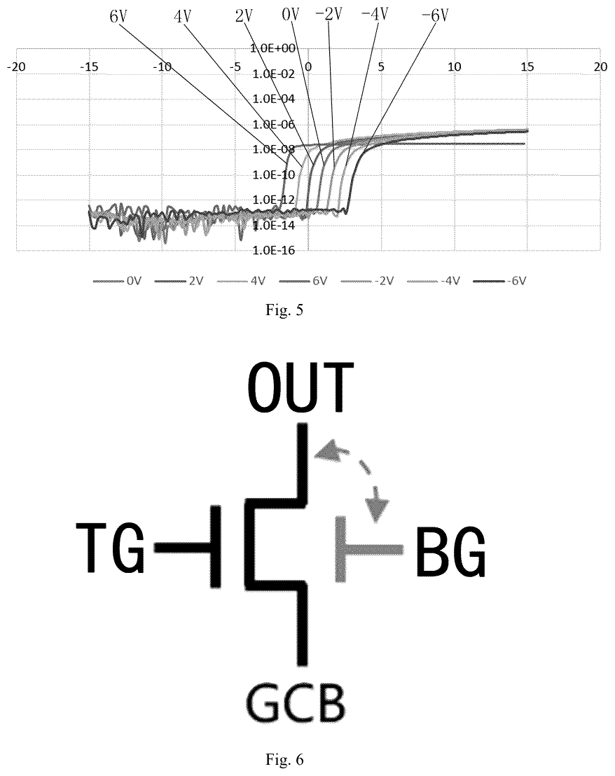

FIG. 5 shows an influence of a potential at the bottom gate electrode BG on characteristics of a transistor. In FIG. 5, an x-axis represents V_{GS1}, i.e., a voltage difference between the top gate electrode TG and a source electrode of the transistor, and a y-axis represents IDs, i.e., a current between the source electrode and a drain electrode of the transistor. FIG. 5 shows the influence on a characteristic curve in a case that voltages at the bottom gate electrode BG is 0V, 2V, 4V, 6V, −2V, −4V and −6V. Hence, through adjusting the voltage at the bottom gate electrode BG, it is able to adjust the characteristic curve of the transistor, even if a negative shift occurs for the transistor.

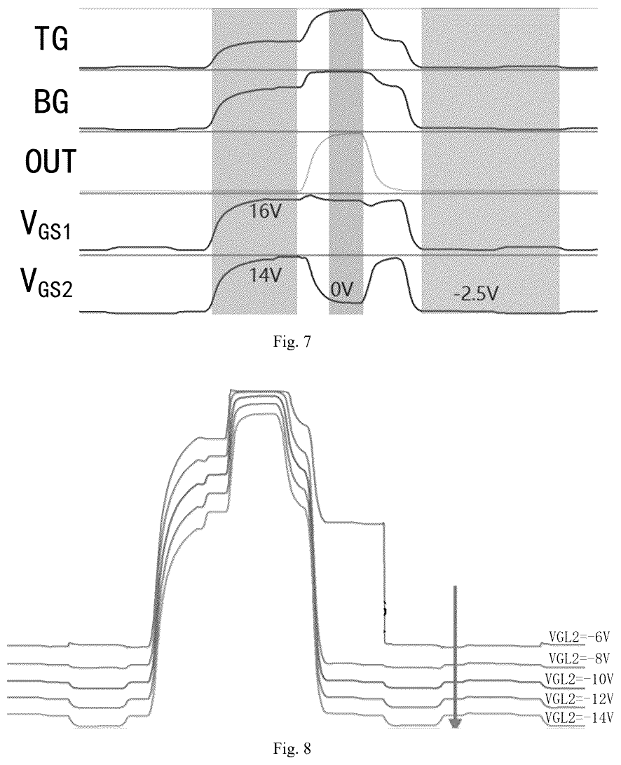

FIG. 6 shows a connection mode of the first output transistor Ts1. The first electrode of the first output transistor Ts1 is coupled to a first clock signal input end GCB, and the second electrode of the first output transistor Ts1 is coupled to the gate driving signal output end OUT. As shown in FIG. 7, V_{GS1} of the first output transistor Ts1 is a voltage difference between the top gate electrode TG and a source electrode of the first output transistor Ts1, and V_{GS2} of the first output transistor Ts1 is a voltage difference between the bottom gate electrode BG and the source electrode of the first output transistor Ts1. A signal waveform of the bottom gate electrode BG changes along with a signal waveform of the top gate electrode TG, and it is also controlled by the control signal input end K0. In FIG. 7, a first hatched region indicates that V_{GS2}>0, a second hatched region indicates that V_{GS2}=0, and a third hatched region indicates that V_{GS2}<0. Through setting V_{GS2} with such a waveform, it is able to adjust a positive shift of the characteristic of the first output transistor Ts1.

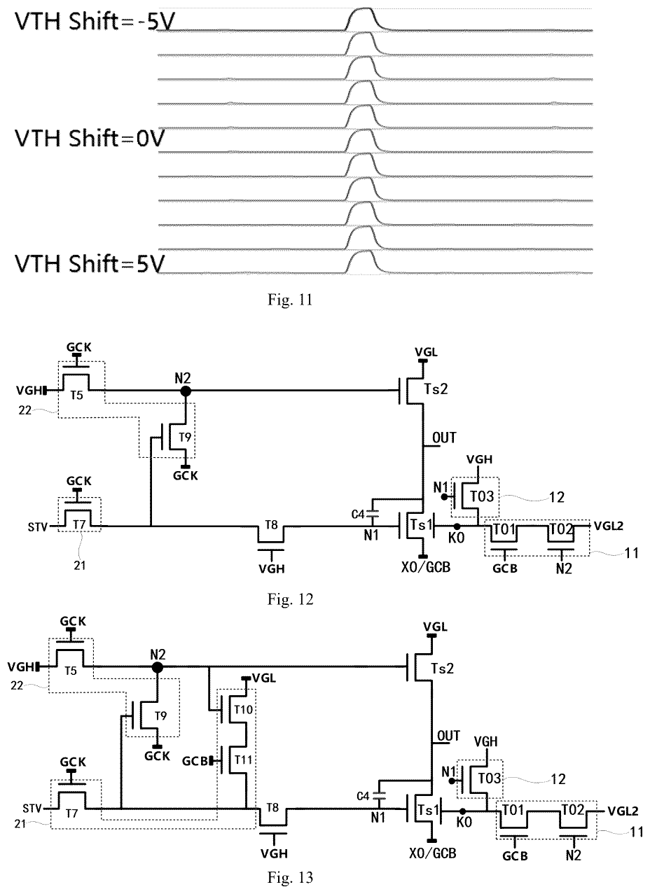

FIG. 3 shows a waveform of a gate driving signal before the improvement in the first output transistor Ts1 in a case that a VTH shift of the first output transistor Ts1 is biased from −5V to +5V. Within a range of −5V to −2V, there is a fluctuation of the outputted gate driving signal. FIG. 11 shows a waveform of the gate driving signal after the improvement in the first output transistor Ts1 in a case that the VTH shift of the first output transistor Ts1 is biased from −5V to +5V. Within a range of −5V to +5V, there is no fluctuation of the outputted gate driving signal.

Based on the above-mentioned specific structure of the shift register unit, in the embodiments of the present disclosure, the first output transistor Ts1 includes the dual-gate structure, the first gate electrode of the first output transistor Ts1 is coupled to the first output control node N1, the second gate electrode of the first output transistor Ts1 is coupled to the control signal input end K0, the first electrode of the first output transistor Ts1 is coupled to the first signal input end X0, and the second electrode of the first output transistor Ts1 is coupled to the gate driving signal output end OUT. Through the first gate electrode and the second gate electrode, it is able to control the first output transistor Ts1 to be turned on or off, thereby to ensure normal operation of the shift register unit. Through adjusting a voltage at the second gate electrode, it is able to adjust the characteristic curve of the first output transistor Ts1, thereby to improve the negative shift of the first output transistor Ts1, and prevent the occurrence of any fluctuation of the outputted gate driving signal.

It should be appreciated that, during the manufacture of an oxide display product, negative shift easily occurs for an oxide transistor, and thereby the shift register unit may fail. A process margin of the oxide transistor needs to be improved. In the shift register unit provided in the embodiments of the present disclosure, the first output transistor Ts1 includes the dual-gate structure, and the voltage at the second gate electrode, i.e., the bottom gate electrode BG, of the first output transistor Ts1 is adjusted, so as to adjust the characteristic curve of the first output transistor Ts1 even if the negative shift occurs for the first output transistor Ts1. Hence, in the shift register unit, it is able to improve the process margin of the first output transistor Ts1, provide the first output transistor Ts1 with such a capability as to adapt to the negative shift with a large range, and ensure the stability of the outputted gate driving signal.

As shown in FIGS. 9 to 13, in some embodiments of the present disclosure, the shift register unit further includes a second output transistor Ts2, a second output control node N2 and a first level signal input end VGL. A gate electrode of the second output transistor Ts2 is coupled to the second output control node N2, a first electrode of the second output transistor Ts2 is coupled to the first level signal input end VGL, and a second electrode of the second output transistor Ts2 is coupled to the gate driving signal output end OUT.

The first signal input end X0 includes a first clock signal input end GCB. The shift register unit further includes a second level signal input end VGL2, a third level signal input end VGH and a control signal debugging unit, and the control signal debugging unit includes a first debugging sub-unit 11 and a second debugging sub-unit 12.

The first debugging sub-unit 11 is coupled to the first clock signal input end GCB, the second output control node N2, the second level signal input end VGL2 and the control signal input end K0, and configured to control the second level signal input end VGL2 to be electrically coupled to or electrically decoupled from the control signal input end K0 under the control of the first clock signal input end GCB and the second output control node N2.

The second debugging sub-unit 12 is coupled to the first output control node N1, the third level signal input end VGH and the control signal input end K0, and configured to control the third level signal input end VGH to be electrically coupled to or electrically decoupled from the control signal input end K0 under the control of the first output control node N1.

Illustratively, the first debugging sub-unit 11 includes a first debugging transistor T01 and a second debugging transistor T02. The second debugging sub-unit 12 includes a third debugging transistor T03. A gate electrode of the first debugging transistor T01 is coupled to the first clock signal input end GCB, a first electrode of the first debugging transistor T01 is coupled to a second electrode of the second debugging transistor T02, and a second electrode of the first debugging transistor T01 is coupled to the control signal input end K0. A gate electrode of the second debugging transistor T02 is coupled to the second output control node N2, and a first electrode of the second debugging transistor T02 is coupled to the second level signal input end VGL2. A gate electrode of the third debugging transistor T03 is coupled to the first output control node N1, a first electrode of the third debugging transistor T03 is coupled to the third level signal input end VGH, and a second electrode of the third debugging transistor T03 is coupled to the control signal input end K0.

Illustratively, in a case that a signal transmitted at the first output control node N1 is an inactive level, the second debugging sub-unit 12 controls the third level signal input end VGH to be electrically decoupled from the control signal input end K0 under the control of the first output control node N1, i.e., the third debugging transistor T03 is turned off. In a case that a signal transmitted at the first clock signal input end GCB and a signal transmitted at the second output control node N2 are active levels, the first debugging sub-unit 11 controls the second level signal input end VGL2 to be electrically coupled to the control signal input end K0 under the control of the first clock signal input end GCB and the second output control node N2, i.e., the first debugging transistor T01 and the second debugging transistor T02 are both turned on so that a potential at the control signal input end K0 is controlled by the second level signal input end VGL2. As shown in FIG. 8, a voltage at the control signal input end K0 changes within a range of −6V to −12V in a case that a voltage value of a second level signal inputted by the second level signal input end VGL2 changes from −6V to −14V.

Illustratively, in a case that the signal transmitted at the first clock signal input end GCB and the signal transmitted at the second output control node N2 are inactive levels, the first debugging sub-unit 11 controls the second level signal input end VGL2 to be electrically decoupled from the control signal input end K0 under the control of the first clock signal input end GCB and the second output control node N2, i.e., the first debugging transistor T01 and the second debugging transistor T02 are both turned off. In a case that the signal transmitted at the first output control node N1 is an active level, the second debugging sub-unit 12 controls the third level signal input end VGH to be electrically coupled to the control signal input end K0 under the control of the first output control node N1, i.e., the third debugging transistor T03 is turned on so that the potential at the control signal input end K0 is controlled by the third level signal input end VGH.

In the above shift register unit provided in the embodiments of the present disclosure, the control signal debugging unit adaptively adjusts the potential at the control signal input end K0 with respect to different operating phases, i.e., different operating states of the first output transistor Ts1, so as to adaptively adjust the potential at the second gate electrode of the first output transistor Ts1 at different operating phases. Hence, in the above shift register unit provided in the embodiments of the present disclosure, it is able to adaptively adjust the characteristic curve of the first output transistor Ts1 according to different operating states of the first output transistor Ts1, thereby to further improve the output stability of the gate driving signal while improving the negative shift of the first output transistor Ts1, and reduce the power consumption of the transistor.

As shown in FIGS. 9, 12 and 13, in some embodiments of the present disclosure, the shift register unit further includes a first node control unit 21, a second node control unit 22, a second clock signal input end GCK and a start signal input end STV. The first node control unit 21 is coupled to the second clock signal input end GCK, the first output control node N1 and the start signal input end STV, and configured to control the start signal input end to be electrically coupled to or electrically decoupled from the first output control node N1 under the control of the second clock signal input end GCK.

As shown in FIG. 9, the second node control unit 22 is coupled to the first clock signal input end GCB, the second clock signal input end GCK, the first level signal input end VGL, the third level signal input end VGH and the second output control node N2, and configured to control the first level signal input end VGL to be electrically coupled to or electrically decoupled from the second output control node N2 under the control of the first clock signal input end VGL, and control the third level signal input end VGH to be electrically coupled to or electrically decoupled from the second output control node N2 under the control of the second clock signal input end GCK. Alternatively, as shown in FIGS. 12 and 13, the second node control unit 22 is coupled to the second clock signal input end GCK, the first output control node N1, the second output control node N2 and the third level signal input end VGH, and configured to control the third level signal input end VGH to be electrically coupled to or electrically decoupled from the second output control node N2 under the control of the second clock signal input end GCK, and control the second clock signal input end GCK to be electrically coupled to or electrically decoupled from the second output control node N2 under the control of the first output control node N1.

Illustratively, the first node control unit 21 includes a seventh transistor T7, a gate electrode of the seventh transistor T7 is coupled to the second clock signal input end GCK, a first electrode of the seventh transistor T7 is coupled to the start signal input end STV, and a second electrode of the seventh transistor T7 is coupled to the first output control node N1.

Illustratively, as shown in FIG. 9, the second node control unit 22 includes a fifth transistor T5 and a sixth transistor T6. A gate electrode of the fifth transistor T5 is coupled to the second clock signal input end GCK, a first electrode of the fifth transistor T5 is coupled to the third level signal input end VGH, and a second electrode of the fifth transistor T5 is coupled to the second output control node N2. A gate electrode of the sixth transistor T6 is coupled to the first clock signal input end GCB, a first electrode of the sixth transistor T6 is coupled to the first level signal input end VGL, and a second electrode of the sixth transistor T6 is coupled to the second output control node N2.

As shown in FIG. 10, at a phase P1, N2 is a high level, N3 is a high level, N1 is a high level, and OUT is a low level. At a phase P2, N2 is a low level, N3 is a high level, N1 is a high level, and OUT is a high level. At a phase P3, N2 is a high level, N3 is a low level, N1 is a low level, and OUT is a low level. At a phase P4, N2 is a high level, N3 is a low level, N1 is a low level, and OUT is a low level. Based on the potentials at these nodes, it is able to calculate a voltage value of V_{GS} during the operation of each transistor.

Illustratively, as shown in FIGS. 12 and 13, the second node control unit 22 includes the fifth transistor T5 and a ninth transistor T9. A gate electrode of the ninth transistor T9 is coupled to the first output control node N1, a first electrode of the ninth transistor T9 is coupled to the second clock signal input end GCK, and a second electrode of the ninth transistor T9 is coupled to the second output control node N2.

Illustratively, the shift register unit further includes an eighth transistor T8, a gate electrode of the eighth transistor T8 is coupled to the third level signal input end VGH, a first electrode of the eighth transistor T8 is coupled to the second electrode of the seventh transistor T7, and a second electrode of the eighth transistor T8 is coupled to the first output control node N1. The shift register unit further includes a fourth capacitor C4, a first plate of the fourth capacitor C4 is coupled to the first output control node N1, and a second plate of the fourth capacitor C4 is coupled to the gate driving signal output end OUT.

It should be appreciated that, as shown in FIG. 13, in a case that the shift register unit further includes the eighth transistor T8, the second electrode of the seventh transistor T7, the gate electrode of the ninth transistor T9 and a second electrode of an eleventh transistor T11 are all coupled to the first output control node N1 via the eighth transistor T8.

As shown in FIG. 13, in some embodiments of the present disclosure, the first node control unit 21 is further coupled to the first clock signal input end GCB, the second output control node N2, and the first level signal input end VGL, and configured to control the first level signal input end VGL to be electrically coupled to or electrically decoupled from the first output control node N1 under the control of the first clock signal input end GCB and the second output control node N2.

Illustratively, the first node control unit 21 further includes a tenth transistor T10 and an eleventh transistor T11. A gate electrode of the tenth transistor T10 is coupled to the second output control node N2, a first electrode of the tenth transistor T10 is coupled to the first level signal input end VGL, a second electrode of the tenth transistor T10 is coupled to a first electrode of the eleventh transistor T11, a second electrode of the eleventh transistor T11 is coupled to the first output control node N1, and a gate electrode of the eleventh transistor T11 is coupled to the first clock signal input end GCB.

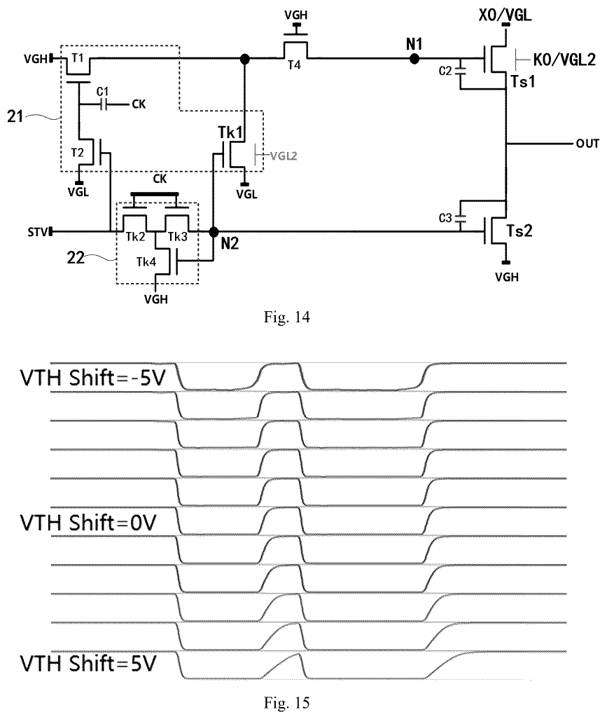

As shown in FIGS. 14 to 17, in some embodiments of the present disclosure, the first signal input end X0 includes a first level signal input end VGL, the control signal input end K0 includes a second level signal input end VGL2, and the second level signal input end VGL2 is configured to input a direct-current second level signal. The shift register unit further includes a second output transistor Ts2, a second output control node N2 and a third level signal input end VGH, a gate electrode of the second output transistor Ts2 is coupled to the second output control node N2, a first electrode of the second output transistor Ts2 is coupled to the third level signal input end VGH, and a second electrode of the second output transistor Ts2 is coupled to the gate driving signal output end OUT.

It should be appreciated that, the above scheme is merely limited to a situation where a source electrode of the first output transistor Ts 1 has a fixed potential, i.e., a voltage at the source electrode does not change randomly, otherwise V_{GS2} may change accordingly, and thereby the characteristic of the transistor changes. Based on the above, the first signal input end X0 includes the first level signal input end VGL so that the source electrode of the first output transistor Ts1 has a same fixed potential as a first level signal, and the control signal input end K0 includes the second level signal input end VGL2 so that the characteristic curve of the first output transistor Ts1 is capable of being adjusted according to the voltage at the second gate electrode. In this way, it is able to improve the negative shift of the first output transistor Ts1, and prevent the occurrence of any fluctuation of the outputted gate driving signal.

In some embodiments of the present disclosure, the shift register unit further includes a first node control unit 21. The first node control unit 21 is coupled to the second output control node N2, the first level signal input end VGL and the first output control node N1, and configured to control the first level signal input end VGL to be electrically coupled to or electrically decoupled from the first output control node N1 under the control of the second output control node N2.

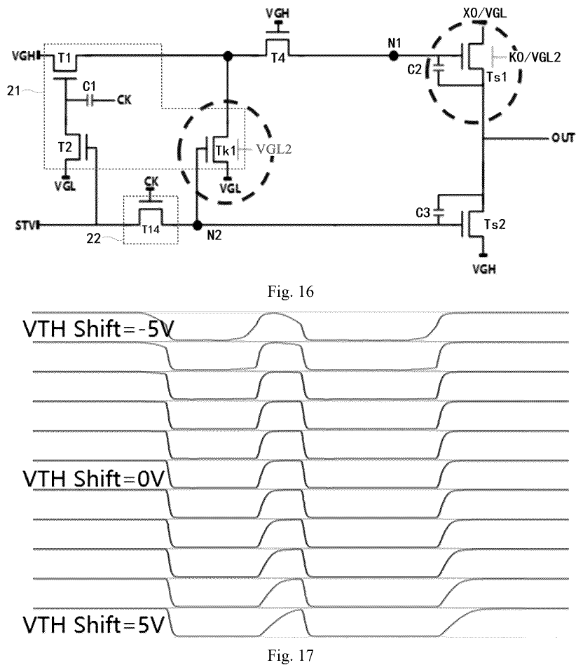

As shown in FIGS. 16 and 17, in some embodiments of the present disclosure, the first node control unit 21 is further coupled to the second level signal input end VGL2. The first node control unit 21 includes a first control transistor Tk1, the first control transistor Tk1 includes a dual-gate structure, a first gate electrode of the first control transistor Tk1 is coupled to the second output control node N2, a second gate electrode of the first control transistor Tk1 is coupled to the second level signal input end VGL2, a first electrode of the first control transistor Tk1 is coupled to the first level signal input end VGL, and a second electrode of the first control transistor Tk1 is coupled to the first output control node N1.

Based on the above, the first control transistor Tk1 includes the dual-gate structure so that the characteristic curve of the first control transistor Tk1 is capable of being adjusted according to the voltage at the second gate electrode of the first control transistor Tk1. In this way, it is able to improve the negative shift of the first control transistor Tk1, and prevent the occurrence of any fluctuation of the outputted gate driving signal.

More specifically, FIG. 17 shows a waveform of the outputted gate driving signal after the improvement in the first control transistor Tk1 in a case that the VTH shift of the first control transistor Tk1 is biased from −5V to +5V. Within a range of −3V to +3V, there is no fluctuation of the outputted gate driving signal.

As shown in FIG. 16, in some embodiments of the present disclosure, the shift register unit further includes a second node control unit 22, a third clock signal input end CK and a start signal input end STV. The second node control unit 22 is coupled to the third clock signal input end CK, the start signal input end STV and the second output control node N2, and configured to control the start signal input end STV to be electrically coupled to or electrically decoupled from the second output control node N2 under the control of the third clock signal input end CK.

Illustratively, the second node control unit 22 includes a fourteenth transistor T14, a gate electrode of the fourteenth transistor T14 is coupled to the third clock signal input end CK, a first electrode of the fourteenth transistor T14 is coupled to the start signal input end STV, and a second electrode of the fourteenth transistor T14 is coupled to the second output control node N2.

As shown in FIGS. 14 and 15, in some embodiments of the present disclosure, the second node control unit 22 is further coupled to the third level signal input end VGH. The second node control unit 22 includes a second control transistor Tk2, a third control transistor Tk3 and a fourth control transistor Tk4. A gate electrode of the second control transistor Tk2 is coupled to the third clock signal input end CK, a first electrode of the second control transistor Tk2 is coupled to the start signal input end STV, and a second electrode of the second control transistor Tk2 is coupled to a first electrode of the third control transistor Tk3. A gate electrode of the third control transistor Tk3 is coupled to the third clock signal input end CK, and a second electrode of the third control transistor Tk3 is coupled to the second output control node N2. A gate electrode of the fourth control transistor Tk4 is coupled to the second output control node N2, a first electrode of the fourth control transistor Tk4 is coupled to the third level signal input end VGH, and a second electrode of the fourth control transistor Tk4 is coupled to the first electrode of the third control transistor Tk3.

Illustratively, a width-to-length ratio of a channel of the fourth control transistor Tk4 is greater than a width-to-length ratio of a channel of the second control transistor Tk2, and/or the width-to-length ratio of the channel of the fourth control transistor Tk4 is greater than a width-to-length ratio of a channel of the third control transistor Tk3.

More specifically, the larger the width-to-length ratio of the channel of the fourth control transistor Tk4, the smaller the resistance of the channel, so as to facilitate the flow of the leakage current to the fourth control transistor Tk4, and achieve the absorption of the leakage current.

FIG. 15 shows a waveform of the outputted gate driving signal in a case that the second node control unit 22 includes the second control transistor Tk2, the third control transistor Tk3 and the fourth control transistor Tk4, and the VTH shift of the second control transistor Tk2 and the third control transistor Tk3 is biased from −5V to +5V. Within a range of −4V to 2V, the fourth control transistor Tk4 absorbs the leakage current well, so as to output the stable gate driving signal.

In the shift register unit provided in the embodiments of the present disclosure, the second node control unit 22 includes the second control transistor Tk2, the third control transistor Tk3 and the fourth control transistor Tk4, so as to ensure that the signal is transmitted via the second control transistor Tk2 and the third control transistor Tk3, and enable the fourth control transistor Tk4 having a channel with a larger width-to-length ratio to absorb a leakage current signal generated due to the characteristic shift of the transistor. In this way, even if the characteristic shift occurs for the second control transistor Tk2 and the third control transistor Tk3, it is able to ensure that the shift register unit normally outputs the gate driving signal. Hence, in the shift register unit provided in the embodiments of the present disclosure, it is able to solve the problem that the outputted gate driving signal is unstable due to the characteristic shift of the transistor as well as an increase in the leakage current, and drive the display region normally, thereby to ensure the display quality of the display product.

Based on the above, the first output transistor Ts1 and the first control transistor Tk1 both have a dual-gate structure, and the characteristic of the transistor is adjusted through adjusting a second level signal received by the second gate electrode of the transistor, so as to optimize the VTH margin through changing the potential at the second gate electrode even in a case of the negative shift of the transistor, thereby to output the stable gate driving signal.

As shown in FIGS. 14 and 16, in some embodiments of the present disclosure, the first node control unit 21 is coupled to the first level signal input end VGL, the third level signal input end VGH and the start signal input end, and configured to control the third level signal input end VGH to be electrically coupled to the first output control node N1 under the control of the first level signal input end VGL and the start signal input end STV.

Illustratively, the first node control unit 21 includes a first transistor T1, a second transistor T2 and a first capacitor C1. A gate electrode of the first transistor T1 is coupled to a second electrode of the second transistor T2, a first electrode of the first transistor T1 is coupled to the third level signal input end VGH, and a second electrode of the first transistor T1 is coupled to the first output control node N1. A gate electrode of the second transistor T2 is coupled to the start signal input end STV, and a first electrode of the second transistor T2 is coupled to the first level signal input end VGL. A first plate of the first capacitor C1 is coupled to the third clock signal input end CK, and a second plate of the first capacitor C1 is coupled to the gate electrode of the first transistor T1.

Illustratively, the shift register unit further includes a fourth transistor T4, a gate electrode of the fourth transistor T4 is coupled to the third level signal input end VGH, a first electrode of the fourth transistor T4 is coupled to the second electrode of the first transistor T1, and a second electrode of the fourth transistor T4 is coupled to the first output control node N1. The shift register unit further includes a second capacitor C2 and a third capacitor C3. A first plate of the second capacitor C2 is coupled to the first output control node N1, and a second plate of the second capacitor C2 is coupled to the gate driving signal output end OUT. A first plate of the third capacitor C3 is coupled to the gate driving signal output end OUT, and a second plate of the third capacitor C3 is coupled to the gate electrode of the second output transistor Ts2.

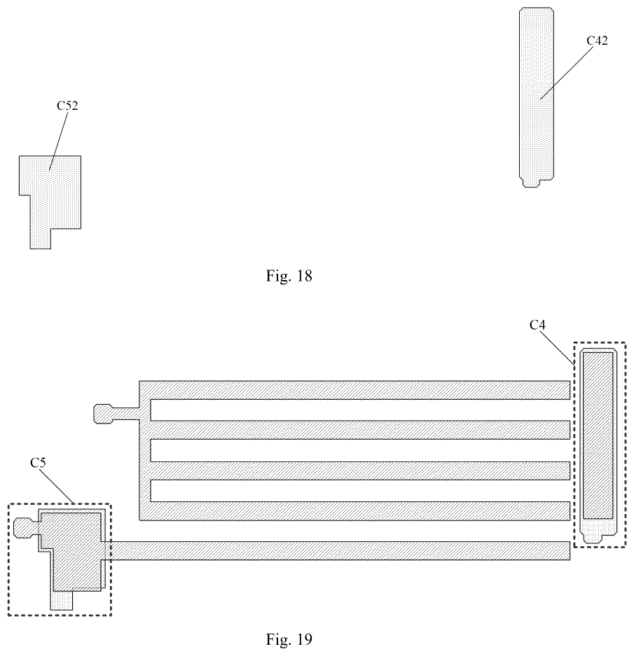

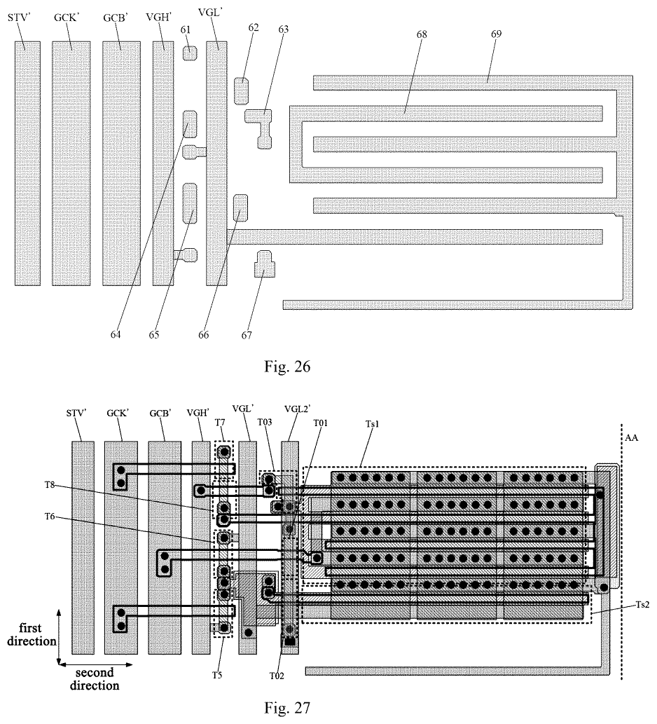

As shown in FIGS. 18 to 27, the present disclosure further provides in some embodiments a display substrate, which includes the above-mentioned shift register unit. The display substrate includes a display region and a peripheral region outside the display region, and the shift register unit is arranged in the display region and/or the peripheral region.

Illustratively, the peripheral region is arranged to, but not limited to, surround the display region.

Illustratively, the peripheral region includes a left bezel region and a right bezel region, and the display region is located between the left bezel region and the right bezel region. The shift register unit is arranged in the left bezel region and/or the right bezel region. The shift register unit may also be arranged in the display region.

In the shift register unit provided in the embodiments of the present disclosure, through the first gate electrode and the second gate electrode, it is able to control the first output transistor Ts1 to be turned on or off, thereby to ensure normal operation of the shift register unit. Through adjusting a voltage at the second gate electrode, it is able to adjust the characteristic curve of the first output transistor Ts1, thereby to improve the negative shift of the first output transistor Ts1, and prevent the occurrence of any fluctuation of the outputted gate driving signal. In the shift register unit provided in the embodiments of the present disclosure, the first output transistor Ts1 includes the dual-gate structure, and the voltage at the second gate electrode, i.e., the bottom gate electrode BG, of the first output transistor Ts1 is adjusted, so as to adjust the characteristic curve of the first output transistor Ts1 even if the negative shift occurs for the first output transistor Ts1. Hence, in the shift register unit, it is able to improve the process margin of the first output transistor Ts1, provide the first output transistor Ts1 with such a capability as to adapt to the negative shift with a large range, and ensure the stability of the outputted gate driving signal.

In a case that the display substrate provided in the embodiments of the present disclosure includes the above-mentioned shift register unit, it also has the above-mentioned beneficial effects. The display substrate is driven by the stable gate driving signal, so as to improve the display quality.

As shown in FIGS. 18 to 27, in some embodiments of the present disclosure, the shift register unit includes a control signal debugging unit, the control signal debugging unit includes a first debugging sub-unit 11 and a second debugging sub-unit 12, the first debugging sub-unit 11 includes a first debugging transistor T01 and a second debugging transistor T02, and the second debugging sub-unit 12 includes a third debugging transistor T03. The shift register unit further includes a first output transistor Ts1 and a second output transistor Ts2. The first output transistor Ts1 and the second output transistor Ts2 are arranged in a first direction, at least a portion of the third debugging transistor T03, the first debugging transistor T01 and the second debugging transistor T02 are arranged in the first direction, and the first output transistor Ts1 is arranged between the display region and the first debugging transistor T01.

Illustratively, the third debugging transistor T03 and the first output transistor Ts1 are arranged in a second direction, the first debugging transistor T01 and the first output transistor Ts1 are arranged in the second direction, and the second debugging transistor T02 and the first output transistor Ts1 are arranged in the second direction.

Illustratively, the first direction intersects the second direction. For example, the first direction includes a longitudinal direction, and the second direction includes a horizontal direction.

Based on the above, the first output transistor Ts1 and the second output transistor Ts2 are arranged in the first direction, and at least a portion of the third debugging transistor T03, the first debugging transistor T01 and the second debugging transistor T02 are arranged in the first direction, so it is able to reduce a width of a space occupied by the first output transistor Ts1, the second output transistor Ts2, the first debugging transistor T01, the second debugging transistor T02 and the third debugging transistor T03 in the second direction, thereby to effectively reduce a width of a bezel of the display substrate.

Based on the above, the first output transistor Ts1 is arranged between the display region and the first debugging transistor T01, so as to utilize a limited layout space, and reduce a layout difficulty of the shift register unit in the limited layout space.

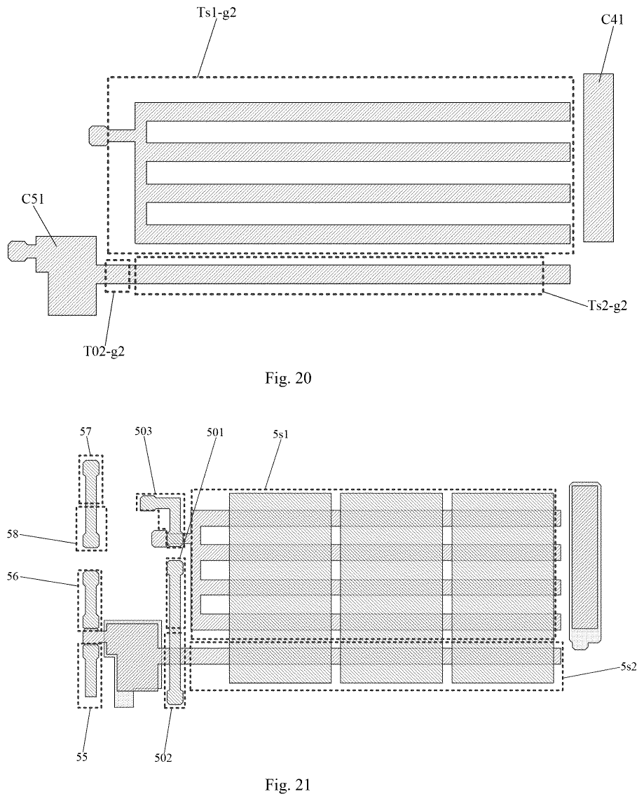

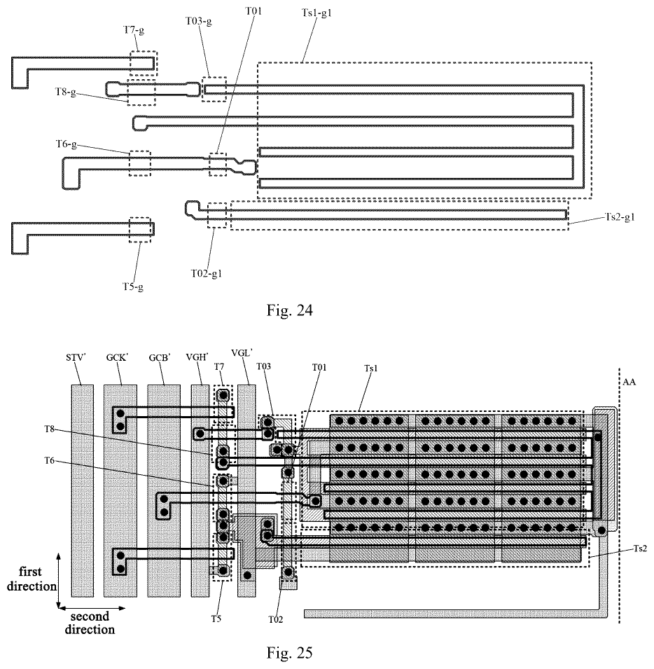

As shown in FIGS. 20 and 24, in some embodiments of the present disclosure, the second debugging transistor T02 and the second output transistor Ts2 both include a dual-gate structure, a first gate electrode T02-g1 of the second debugging transistor T02 and a first gate electrode Ts2-g1 of the second output transistor Ts2 form a one-piece structure, and a second gate electrode T02-g2 of the second debugging transistor T02 and a second gate electrode of the second output transistor Ts2 form a one-piece structure.

Based on the above, the second debugging transistor T02 and the second output transistor Ts2 both include the dual-gate structure, so as to improve the performance of the second debugging transistor T02 and the second output transistor Ts2 in a better manner. In addition, the above-mentioned structures are formed as a one-piece structure, so as to not only ensure the coupling performance between the structures, but also simplify the manufacture process and reduce the manufacture cost.

As shown in FIG. 24, in some embodiments of the present disclosure, a gate electrode T03-g of the third debugging transistor T03 and a first gate electrode Ts1-g1 of the first output transistor Ts1 form a one-piece structure.

The above-mentioned structures are formed as a one-piece structure, so as to not only ensure the coupling performance between the structures, but also simplify the manufacture process and reduce the manufacture cost.

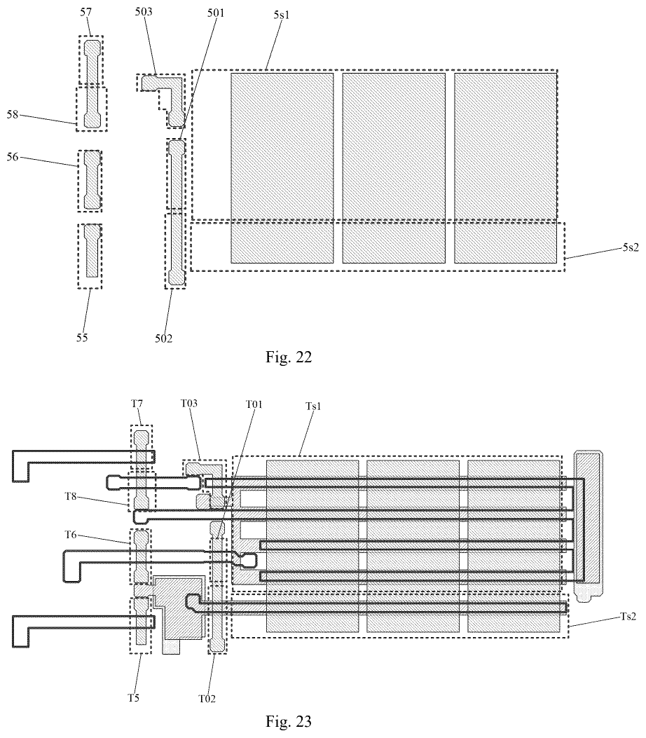

As shown in FIGS. 22 and 27, in some embodiments of the present disclosure, the display substrate further includes a second level signal line VGL2′, and the second level signal line VGL2′, as a second level signal input end VGL2, is coupled to the second debugging transistor T02.

The first debugging transistor T01 includes a first debugging active layer 501, the second debugging transistor T02 includes a second debugging active layer 502, and the third debugging transistor T03 includes a third debugging active layer 503.

An orthogonal projection of the second level signal line VGL2′ onto a base substrate of the display substrate at least partially overlaps with an orthogonal projection of the first debugging active layer 501 onto the base substrate of the display substrate, and/or the orthogonal projection of the second level signal line VGL2′ onto the base substrate of the display substrate at least partially overlaps with an orthogonal projection of the second debugging active layer 502 onto the base substrate of the display substrate, and/or the orthogonal projection of the second level signal line VGL2′ onto the base substrate of the display substrate at least partially overlaps with an orthogonal projection of the third debugging active layer 503 onto the base substrate of the display substrate.

Illustratively, the first debugging active layer 501, the second debugging active layer 502 and the third debugging active layer 503 all include, but not limited to, oxide active layers, e.g., Indium Gallium Zinc Oxide (IGZO) active layers.

Illustratively, the second level signal line VGL2′ includes at least a portion extending in the first direction. The first debugging active layer 501 and the second debugging active layer 502 both extend in the first direction, and the third debugging active layer 503 includes a portion extending in the first direction and a portion extending in the second direction.

Illustratively, the orthogonal projection of the first debugging active layer 501 onto the base substrate is located within the orthogonal projection of the second level signal line VGL2′ onto the base substrate. The orthogonal projection of the second debugging active layer 502 onto the base substrate is located within the orthogonal projection of the second level signal line VGL2′ onto the base substrate. The orthogonal projection of the third debugging active layer 503 onto the base substrate is located within the orthogonal projection of the second level signal line VGL2′ onto the base substrate.

Illustratively, the second debugging active layer 502 and the first debugging active layer 501 form a one-piece structure.

Based on the above, it is able to reduce a layout space individually occupied by the second level signal line VGL2′, thereby to provide the display substrate with a narrow bezel.

As shown in FIGS. 18 to 27, in some embodiments of the present disclosure, the display substrate further includes a first level signal line VGL′ and a third level signal line VGH′. The first level signal line VGL′, as a first level signal input end VGL, is coupled to the second output transistor Ts2, and the third level signal line VGH′, as a third level signal input end VGH, is coupled to the third debugging transistor T03. In a direction close to the display region, an orthogonal projection of the third level signal line VGH′ onto the base substrate, an orthogonal projection of the first level signal line VGL′ onto the base substrate and the orthogonal projection of the second level signal line VGL2′ onto the base substrate are arranged sequentially.

Illustratively, the first level signal line VGL′ includes at least a portion extending in the first direction, and the third level signal line VGH′ includes at least a portion extending in the first direction.

As shown in FIGS. 18 to 27, in some embodiments of the present disclosure, the display substrate further includes a first clock signal line GCB′, a second clock signal line GCK′ and a start signal line STV′. The first clock signal line GCB′, as a first clock signal input end GCB, is coupled to the first debugging transistor T01. The shift register unit further includes a fifth transistor T5, a sixth transistor T6, a seventh transistor T7 and an eighth transistor T8.

A gate electrode of the fifth transistor T5 is coupled to the second clock signal line GCK′, a first electrode of the fifth transistor T5 is coupled to the third level signal line VGH′, and a second electrode of the fifth transistor T5 is coupled to a gate electrode of the second output transistor Ts2.

A gate electrode of the sixth transistor T6 is coupled to the first clock signal line GCB′, a first electrode of the sixth transistor T6 is coupled to the first level signal line VGL′, and a second electrode of the sixth transistor T6 is coupled to the gate electrode of the second output transistor Ts2.

A gate electrode of the seventh transistor T7 is coupled to the second clock signal line GCK′, a first electrode of the seventh transistor T7 is coupled to the start signal line STV′, a second electrode of the seventh transistor T7 is coupled to a first electrode of the eighth transistor T8, a second electrode of the eighth transistor T8 is coupled to a gate electrode of the first output transistor Ts1, and a gate electrode of the eighth transistor T8 is coupled to the third level signal line VGH′. It should be appreciated that, in a case that the display substrate includes a plurality of the cascaded shift register units, the first electrode of the seventh transistor T7 in a first-level shift register unit is directly coupled to the start signal line STV′, and a first electrode of the seventh transistor T7 in the other level of shift register unit is coupled to a gate driving signal output end OUT of a previous-level shift register unit.

The seventh transistor T7, the eighth transistor T8, the sixth transistor T6 and the fifth transistor T5 are arranged sequentially in the first direction; and an orthogonal projection of the seventh transistor T7 onto the base substrate, an orthogonal projection of the eighth transistor T8 onto the base substrate, an orthogonal projection of the sixth transistor T6 onto the base substrate and an orthogonal projection of the fifth transistor T5 onto the base substrate are arranged between the orthogonal projection of the third level signal line VGH′ onto the base substrate and the orthogonal projection of the first level signal line VGL′ onto the base substrate.

Illustratively, in the direction close to the display region, the start signal line STV′, the second clock signal line GCK′, the first clock signal line GCB′ and the third level signal line VGH′ are arranged sequentially.

Based on the above, the seventh transistor T7, the eighth transistor T8, the sixth transistor T6 and the fifth transistor T5 are arranged sequentially in the first direction, so it is able to reduce a width of a layout space occupied by the seventh transistor T7, the eighth transistor T8, the sixth transistor T6 and the fifth transistor T5 in the second direction, thereby to effectively reduce a width of a bezel of the display substrate.

In addition, the orthogonal projection of the eighth transistor T8 onto the base substrate, the orthogonal projection of the sixth transistor T6 onto the base substrate and the orthogonal projection of the fifth transistor T5 onto the base substrate are arranged between the orthogonal projection of the third level signal line VGH′ onto the base substrate and the orthogonal projection of the first level signal line VGL′ onto the base substrate, so it is able to utilize a limited layout space, reduce a layout complexity, and reduce a layout difficulty of the shift register unit in the limited layout space while ensuring the coupling performance between the transistor and the signal line.

Moreover, in the display substrate provided in the embodiments of the present disclosure, it is able to optimize a lamination design of the transistors in the shift register unit, and driving the shift register unit efficiently.

More specifically, FIG. 18 shows a second plate C42 of a fourth capacitor C4 and a second plate C52 of a fifth capacitor C5, FIG. 19 shows the fourth capacitor C4 and the fifth capacitor C5, and FIG. 20 shows a first plate C41 of the fourth capacitor C4 and a first plate C51 of the fifth capacitor C5.

FIGS. 21 and 22 show a first output active layer 5s1 of the first output transistor Ts1, a second output active layer 5s2 of the second output transistor Ts2, a first debugging active layer 501 of the first debugging transistor T01, a second debugging active layer 502 of the second debugging transistor T02, a third debugging active layer 503 of the third debugging transistor T03, a fifth active layer 55 of the fifth transistor T5, a sixth active layer 56 of the sixth transistor T6, a seventh active layer 57 of the seventh transistor T7 and an eighth active layer 58 of the eighth transistor T8.

FIG. 24 shows a gate electrode T01-g of the first debugging transistor T01, a gate electrode T5-g of the fifth transistor T5, a gate electrode T6-g of the sixth transistor T6, a gate electrode T7-g of the seventh transistor T7 and a gate electrode T8-g of the eighth transistor T8.

It should be appreciated that, black dots in FIG. 25 represent connection holes between a first source/drain metal layer and film layers under the first source/drain metal layer, and a black square hole in FIG. 27 is used for the connection of the second level signal line VGL2′ with a seventh conductive connection member 67.

As shown in FIGS. 18 to 27, a first conductive connection member 61 is coupled to the first electrode of the seventh transistor T7, a second conductive connection member 62 is coupled to one electrode of the third debugging transistor T03 and the gate electrode of the eighth transistor T8, and the gate electrode of the eighth transistor T8 is coupled to the third level signal VGH′.

A third conductive connection member 63 is coupled to the other electrode of the third debugging transistor T03, the second gate electrode of Ts1-g2 of the first output transistor Ts1, and one electrode of the first debugging transistor T01.

A fourth conductive connection member 64 is coupled to one electrode of the eighth transistor T8 and the first gate electrode Ts1-g1 of the first output transistor Ts1.

A fifth conductive connection member 65 is coupled to one electrode of the sixth transistor T6, the first plate C51 of the fifth capacitor C5 and one electrode of the fifth transistor T5.

A sixth conductive connection member 66 is coupled to the first plate C51 of the fifth capacitor C5 and the first gate electrode Ts2-g1 of the second output transistor Ts2.

The seventh conductive connection member 67 is coupled to one electrode of the second debugging transistor T02 and the second level signal line VGL2′.

An eighth conductive connection member 68 and a portion of a ninth conductive connection member 69 serve as electrodes of the first output transistor Ts1, and the other portion of the ninth conductive connection member 69 serves as an electrode of the second output transistor Ts2.

It should be appreciated that, the display substrate provided in the embodiments of the present disclosure includes, but not limited to, the shift register unit in FIG. 9.

The present disclosure further provides in some embodiments a display device, which includes the above-mentioned display substrate.

It should be appreciated that, the display device may be any product or member having a display function, e.g., television, display, digital photo frame, mobile phone or tablet computer. The display device further includes a flexible circuit board, a printed circuit board, a back plate, etc.

In a case that the display substrate provided in the embodiments of the present disclosure includes the above-mentioned shift register unit, it is able to achieve an excellent display effect. In a case that the display device includes the above-mentioned display substrate, it also has the above-mentioned beneficial effect, which will not be particularly defined herein.

It should be appreciated that, in the case that a signal line extends along a direction X, it means that a primary portion of the signal line, e.g., a line, a segment or a strip-like body, extends along the direction X, and an extension length of the primary portion is greater than an extension length of a secondary portion of the signal line, which is coupled to the primary portion, in the other direction.

It should be further appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are merely for illustrative purposes, but shall not be construed as limiting the scope of the present disclosure. Any person skilled in the art may make modifications and substitutions without departing from the spirit of the present disclosure, and these modifications and substitutions shall also fall within the scope of the present disclosure. Hence, the scope of the present disclosure shall be subject to the scope defined by the appended claims.

1. A shift register unit, comprising a first output transistor, a gate driving signal output end, a first output control node, a control signal input end and a first signal input end, wherein the first output transistor comprises a dual-gate structure, a first gate electrode of the first output transistor is electrically coupled to the first output control node, a second gate electrode of the first output transistor is coupled to the control signal input end, a first electrode of the first output transistor is coupled to the first signal input end, and a second electrode of the first output transistor is coupled to the gate driving signal output end.

2. The shift register unit according to claim 1, further comprising a second output transistor, a second output control node and a first level signal input end, wherein a gate electrode of the second output transistor is coupled to the second output control node, a first electrode of the second output transistor is coupled to the first level signal input end, and a second electrode of the second output transistor is coupled to the gate driving signal output end;
the first signal input end comprises a first clock signal input end; the shift register unit further comprises a second level signal input end, a third level signal input end and a control signal debugging unit, and the control signal debugging unit comprises a first debugging sub-unit and a second debugging sub-unit;
the first debugging sub-unit is coupled to the first clock signal input end, the second output control node, the second level signal input end and the control signal input end, and configured to control the second level signal input end to be electrically coupled to or electrically decoupled from the control signal input end under the control of the first clock signal input end and the second output control node; and
the second debugging sub-unit is coupled to the first output control node, the third level signal input end and the control signal input end, and configured to control the third level signal input end to be electrically coupled to or electrically decoupled from the control signal input end under the control of the first output control node.

3. The shift register unit according to claim 2, wherein the first debugging sub-unit comprises a first debugging transistor and a second debugging transistor; the second debugging sub-unit comprises a third debugging transistor;
a gate electrode of the first debugging transistor is coupled to the first clock signal input end, a first electrode of the first debugging transistor is coupled to a second electrode of the second debugging transistor, and a second electrode of the first debugging transistor is coupled to the control signal input end;
a gate electrode of the second debugging transistor is coupled to the second output control node, and a first electrode of the second debugging transistor is coupled to the second level signal input end; and
a gate electrode of the third debugging transistor is coupled to the first output control node, a first electrode of the third debugging transistor is coupled to the third level signal input end, and a second electrode of the third debugging transistor is coupled to the control signal input end.

4. The shift register unit according to claim 2, further comprising a first node control unit, a second node control unit, a second clock signal input end and a start signal input end,
wherein the first node control unit is coupled to the second clock signal input end, the first output control node and the start signal input end, and configured to control the start signal input end to be electrically coupled to or electrically decoupled from the first output control node under the control of the second clock signal input end,
wherein the second node control unit is coupled to the first clock signal input end, the second clock signal input end, the first level signal input end, the third level signal input end and the second output control node, and configured to control the first level signal input end to be electrically coupled to or electrically decoupled from the second output control node under the control of the first clock signal input end, and control the third level signal input end to be electrically coupled to or electrically decoupled from the second output control node under the control of the second clock signal input end; or
the second node control unit is coupled to the second clock signal input end, the first output control node, the second output control node and the third level signal input end, and configured to control the third level signal input end to be electrically coupled to or electrically decoupled from the second output control node under the control of the second clock signal input end, and control the second clock signal input end to be electrically coupled to or electrically decoupled from the second output control node under the control of the first output control node.

5. The shift register unit according to claim 4, wherein the first node control unit is further coupled to the first clock signal input end, the second output control node and the first level signal input end, and configured to control the first level signal input end to be electrically coupled to or electrically decoupled from the first output control node under the control of the first clock signal input end and the second output control node.

6. The shift register unit according to claim 1, wherein the first signal input end comprises a first level signal input end, the control signal input end comprises a second level signal input end, and the second level signal input end is configured to input a direct-current second level signal; and
the shift register unit further comprises a second output transistor, a second output control node and a third level signal input end, a gate electrode of the second output transistor is coupled to the second output control node, a first electrode of the second output transistor is coupled to the third level signal input end, and a second electrode of the second output transistor is coupled to the gate driving signal output end.

7. The shift register unit according to claim 6, further comprising a first node control unit, wherein the first node control unit is coupled to the second output control node, the first level signal input end and the first output control node, and configured to control the first level signal input end to be electrically coupled to or electrically decoupled from the first output control node under the control of the second output control node.

8. The shift register unit according to claim 7, wherein the first node control unit is further coupled to the second level signal input end, the first node control unit comprises a first control transistor, the first control transistor comprises a dual-gate structure, a first gate electrode of the first control transistor is coupled to the second output control node, a second gate electrode of the first control transistor is coupled to the second level signal input end, a first electrode of the first control transistor is coupled to the first level signal input end, and a second electrode of the first control transistor is coupled to the first output control node.

9. The shift register unit according to claim 6, further comprising a second node control unit, a third clock signal input end and a start signal input end, wherein the second node control unit is coupled to the third clock signal input end, the start signal input end and the second output control node, and configured to control the start signal input end to be electrically coupled to or electrically decoupled from the second output control node under the control of the third clock signal input end.

10. The shift register unit according to claim 9, wherein the second node control unit is further coupled to the third level signal input end; the second node control unit comprises a second control transistor, a third control transistor and a fourth control transistor;
a gate electrode of the second control transistor is coupled to the third clock signal input end, a first electrode of the second control transistor is coupled to the start signal input end, and a second electrode of the second control transistor is coupled to a first electrode of the third control transistor;
a gate electrode of the third control transistor is coupled to the third clock signal input end, and a second electrode of the third control transistor is coupled to the second output control node; and
a gate electrode of the fourth control transistor is coupled to the second output control node, a first electrode of the fourth control transistor is coupled to the third level signal input end, and a second electrode of the fourth control transistor is coupled to the first electrode of the third control transistor.

11. The shift register unit according to claim 7, wherein the first node control unit is further coupled to the first level signal input end, the third level signal input end and the start signal input end, and configured to control the third level signal input end to be electrically coupled to or electrically decoupled from the first output control node under the control of the first level signal input end and the start signal input end.

12. A display substrate, comprising the shift register unit according to claim 1, wherein the display substrate comprises a display region and a peripheral region outside the display region, and the shift register unit is arranged in the display region and/or the peripheral region.

13. The display substrate according to claim 12, wherein the shift register unit comprises a control signal debugging unit, the control signal debugging unit comprises a first debugging sub-unit and a second debugging sub-unit, the first debugging sub-unit comprises a first debugging transistor and a second debugging transistor, and the second debugging sub-unit comprises a third debugging transistor;
the shift register unit further comprises a first output transistor and a second output transistor;
the first output transistor and the second output transistor are arranged in a first direction;
at least a portion of the third debugging transistor, the first debugging transistor and the second debugging transistor are arranged in the first direction; and
the first output transistor is arranged between the display region and the first debugging transistor.

14. The display substrate according to claim 13, wherein the second debugging transistor and the second output transistor both comprise a dual-gate structure, a first gate electrode of the second debugging transistor and a first gate electrode of the second output transistor form a one-piece structure, and a second gate electrode of the second debugging transistor and a second gate electrode of the second output transistor form a one-piece structure.

15. The display substrate according to claim 13, wherein a gate electrode of the third debugging transistor and a first gate electrode of the first output transistor form a one-piece structure.

16. The display substrate according to claim 12, further comprising a second level signal line, wherein the second level signal line, as a second level signal input end, is coupled to the second debugging transistor;
the first debugging transistor comprises a first debugging active layer, the second debugging transistor comprises a second debugging active layer, and the third debugging transistor comprises a third debugging active layer; and
an orthogonal projection of the second level signal line onto a base substrate of the display substrate at least partially overlaps with an orthogonal projection of the first debugging active layer onto the base substrate of the display substrate, and/or the orthogonal projection of the second level signal line onto the base substrate of the display substrate at least partially overlaps with an orthogonal projection of the second debugging active layer onto the base substrate of the display substrate, and/or the orthogonal projection of the second level signal line onto the base substrate of the display substrate at least partially overlaps with an orthogonal projection of the third debugging active layer onto the base substrate of the display substrate.

17. The display substrate according to claim 16, further comprising a first level signal line and a third level signal line, wherein the first level signal line, as a first level signal input end, is coupled to the second output transistor, and the third level signal line, as a third level signal input end, is coupled to the third debugging transistor; and
in a direction close to the display region, an orthogonal projection of the third level signal line onto the base substrate, an orthogonal projection of the first level signal line onto the base substrate and the orthogonal projection of the second level signal line onto the base substrate are arranged sequentially.

18. The display substrate according to claim 17, further comprising a first clock signal line, a second clock signal line and a start signal line, wherein the first clock signal line, as a first clock signal input end, is coupled to the first debugging transistor; the shift register unit further comprises a fifth transistor, a sixth transistor, a seventh transistor and an eighth transistor;
a gate electrode of the fifth transistor is coupled to the second clock signal line, a first electrode of the fifth transistor is coupled to the third level signal line, and a second electrode of the fifth transistor is coupled to a gate electrode of the second output transistor;
a gate electrode of the sixth transistor is coupled to the first clock signal line, a first electrode of the sixth transistor is coupled to the first level signal line, and a second electrode of the sixth transistor is coupled to the gate electrode of the second output transistor;
a gate electrode of the seventh transistor is coupled to the second clock signal line, a first electrode of the seventh transistor is coupled to the start signal line, a second electrode of the seventh transistor is coupled to a first electrode of the eighth transistor, a second electrode of the eighth transistor is coupled to a gate electrode of the first output transistor, and a gate electrode of the eighth transistor is coupled to the third level signal line;
the seventh transistor, the eighth transistor, the sixth transistor and the fifth transistor are arranged sequentially in the first direction; and
an orthogonal projection of the seventh transistor onto the base substrate, an orthogonal projection of the eighth transistor onto the base substrate, an orthogonal projection of the sixth transistor onto the base substrate and an orthogonal projection of the fifth transistor onto the base substrate are arranged between the orthogonal projection of the third level signal line onto the base substrate and the orthogonal projection of the first level signal line onto the base substrate.

19. The display substrate according to claim 18, wherein in the direction close to the display region, the start signal line, the second clock signal line, the first clock signal line and the third level signal line are arranged sequentially.

20. A display device, comprising the display substrate according to claim 12.
